(19) United States
(12) Patent Application Publication
(10) Pub. No.: US 2009/0098469 A1
(43) Pub. Date: Apr. 16, 2009

(54) Process for fabrication of alternating phase shift masks

(76) Inventors: Kishore K. Chakravorty, San Jose, CA (US); Sven Henrichs, San Jose, CA (US); Yi-Ping Liu, San Jose, CA (US); Henry Yun, Sunnyvale, CA (US); Brian Irving, Mountain View, CA (US); Alexander Tritchkov, Hillsboro, OR (US); Karmen Yung, Santa Clara, CA (US)

Correspondence Address: SETH KALSON;c/o CPA Global, P.O. BOX 52050, MINNEAPOLIS, MN, 55402, US

(21) Appl. No.: 11/974,249

(22) Filed: Oct. 12, 2007

(51) Int. Cl. G03F 1/00; B44C 1/22

(52) U.S. Cl. 430/5; 216/12

(57) ABSTRACT

Design rules are described for a phase alternating shift mask for minimum chrome width and maximum segment length, where an embodiment employs during a cleaning process of the mask a megasonic power of 50 Watts at 1 MHz, and 30 Watts at 3 MHz. Some embodiments utilize an dry etch Carbon Tetrafluoride and Dioxygen based process. Other embodiments are described and claimed.

### FIELD

Embodiments of the present invention relate to semiconductor process technology and fabrication, and more particularly, to mask fabrication.

### BACKGROUND

An Alternating Phase Shift Mask (APSM) comprises two adjacent quartz apertures (or clear areas), separated by a chrome region. Quartz is etched to different depths in the two apertures so as to introduce a 180 degree phase shift in the transmitting light. Often, the sidewalls of the quartz trenches scatter light, thereby lowering the intensity transmitting light through the apertures. This asymmetry in the intensity of transmitted light impacts the printability, and gives rise to what is called an imbalance in the printed image. In some prior art, the quartz trenches are laterally etched or undercut, so as to recede the sidewalls away from the chrome opening and thus minimize the scattering loss of the light exiting from the chrome opening.

There are different versions of the prior art relating to the way the structure may be configured. In a dual sided trenched architecture, both the trenches (apertures) are laterally etched. In the single sided trenched architecture, only the deeper trench is laterally etched. In a third variation, a combination of both vertical and lateral etching may be used to correct the image imbalance.

### BRIEF DESCRIPTION OF THE DRAWINGS

FIG. 1 illustrates an embodiment according to the present invention.

FIG. 2 illustrates another embodiment according to the present invention.

### DESCRIPTION OF EMBODIMENTS

In the description that follows, the scope of the term “some embodiments” is not to be so limited as to mean more than one embodiment, but rather, the scope may include one embodiment, more than one embodiment, or perhaps all embodiments.

In fabricating a mask pattern, a form of OPC (Optical Proximity Correction) shaves off chrome lines in steps called jogs. As a result, the line width is reduced in corrected regions. After the quartz etch, these regions form deep thin quartz ridges capped by narrow chrome. These narrow ridges are delicate and prone to fracture. In order to reduce the image imbalance, an undercut etch usually is employed.

This lateral undercutting of the quartz sidewall may further reduce the width of the quartz ridges, thereby increasing its vulnerability. Undercutting further reduces the overlap area between the chrome line and the underlying quartz base, thereby adding to its vulnerability.

As a result, damage, or defects, may be introduced during a cleaning step applied to the APSM.

As discussed above, OPC may involve shaving off chrome lines in steps called jogs. To determine the minimum chrome size required for robustness, for a given undercut, an empirically based approach was used. (Here, chrome refers to chrome plating with Chromium. In the description and drawings, this is simply referred to as chrome.) A test pattern was designed. Notches were created in a long chrome line to create regions of varying chrome widths that mimic the OPC corrected chrome regions present in the mask pattern. The number of Jogs employed for the OPC correction determines the length of the region where chrome is narrowed. In a test pattern, the notch length was varied to mimic this parameter.

Test patterns containing layout were optimized to solve a potential inspection issue. The expected problem was that too many of the “weaker” structures would lift off well before the “stronger” structures, thereby causing issues with the inspection of the test pattern using established defect inspection tools. Knowing this, the layout was optimized so as to place the stronger structures at the beginning of the inspection scan, and the weaker ones at the end. This layout allowed inspection to run until it “choked” on too many defects, and yet there still would be an accurate count from the stronger structures.

The test patterns were processed using a process flow that includes exposure to cleaning steps that are considered likely to cause damage. Correlation between the minimum chrome width and segment length versus the number of cleaning cycles provided the basis for defining the mask design space.

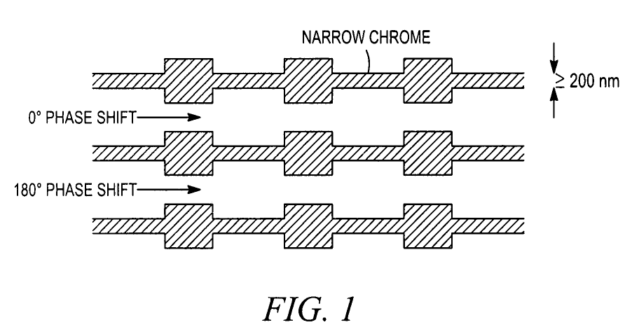

The resulting measured data indicated that reducing the chrome width below 160 nm significantly increased the chrome and quartz rupture occurrences, and indicated that a 160 nm wide chrome line could not be supported without defects unless the segment length was restricted to below three segment lengths, or 600 nm. Accordingly, embodiments of the present invention restrict the minimum chrome feature size of a poly mask, e.g., APSM, to 100 m and the segment length to below three segment lengths equaling 900 nm. The propensity for chrome and quartz damage corresponding to such embodiments is expected to be relatively low. FIG. 1 illustrates, in simplified form, a mask according to an embodiment of the present invention, illustrating narrow chrome features not less than 100 nm.

Experiments were also performed to optimize various critical process steps. For example, spray cleaning was optimized to minimize the damage during the cleaning steps. It was empirically determined that megasonic cleaning power is one of the most critical factors in precipitating damage during the cleaning process. While Megasonic cleaning is used to remove contamination, it tends to induce chrome and quartz damage. Experiments were performed to optimize the megasonic cleaning power to reduce the reticle damage, while still retaining cleanability. It was found that a megasonic power setting of 50 Watts at 1 MHz, and 30 Watts at 3MHz, provided effective cleanability with minimal chrome and quartz damage. Other embodiments may use different power settings and frequency settings. For example, some embodiments may have megasonic power settings within 20% of the above cited examples.

Experiments were also performed to optimize the etch process so as to mitigate the formation of deep fissures within quartz that may lead to premature rupture during the cleaning process. It was found that the enlargement of the quartz defects or decoration depends critically on the etch process employed. In general, a dry etch produced less decoration than a wet HF (Hydrogen Fluoride) based etch process. Accordingly, embodiments may use a single or multiple Fluorine containing gas in a mixture with Oxygen. For example, some embodiments may employ a CF₄ (Carbon Tetrafluoride) and O₂ (Dioxygen) based dry etch process. This process was found to significantly reduced defect creation and to improve the structural integrity of the structures. This dry etch process provided a lateral-to-vertical etch selectivity of 1:2 or better. For some embodiments, the etch time was adjusted so as to get the same 37 nm nominal lateral undercut depth as in the prior wet etch process, thus ensuring equivalent image balance performance. (The zero and π apertures image roughly the same size on the wafer.) For some embodiments, OPC matching was demonstrated to ensure no impact on the printability. This dry etch process implementation was found to mitigate formation of enlarged fissures or defects in the quartz, and mitigated the chrome and quartz damage-induced defects.

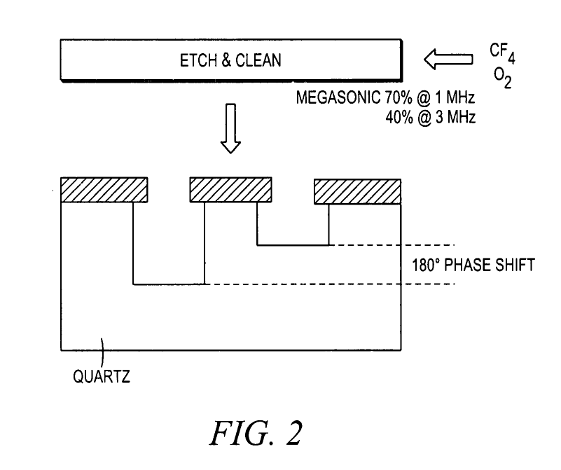

FIG. 2 illustrates in simplified form a process on a mask comprising chrome and quartz, showing two quartz apertures to provide a 180° phase shift, where a dry etch process using CF₄ and O₂ is performed to provide the etch; and a megasonic power setting of 70% (relative to a peak 70 Watts) at 1 MHz, and 40% at 3 MHz.

Various mathematical relationships may be used to describe relationships among one or more quantities. For example, a mathematical relationship may indicate that a quantity is larger, smaller, or equal to another quantity. Such relationships are in practice not satisfied exactly, and should therefore be interpreted as “designed for” relationships. One of ordinary skill in the art may design various working embodiments to satisfy various mathematical relationships, but these relationships can only be met within the tolerances of the technology available to the practitioner.

Accordingly, in the following claims, it is to be understood that claimed mathematical relationships can in practice only be met within the tolerances or precision of the technology available to the practitioner, and that the scope of the claimed subject matter includes those embodiments that substantially satisfy the mathematical relationships so claimed.

What is claimed is:

1. A process comprising:
megasonic cleaning an alternating phase shift mask with a megasonic power in a range 40 to 60 Watts at 1 MHz; and
dry etching the alternating phase shift mask to provide a lateral-to-vertical etch selectivity of approximately 1:2 or better;
the alternating phase shift mask comprising chrome having features not less than 100 nm;

2. The process as set forth in claim 1, further comprising:
megasonic cleaning with a megasonic power in the range of 24 to 36 Watts at 3 MHz.

3. The process as set forth in claim 2, the chrome having wide and narrow regions, wherein each of the narrow regions has a length not greater than 900 nm.

4. The process as set forth in claim 2, further comprising:
dry etching the alternating phase shift mask with a single or multiple Fluorine containing gas in a mixture with Oxygen.

5. The process as set forth in claim 4, the chrome having wide and narrow regions, wherein each of the narrow regions has a length not greater than 900 nm.

6. The process as set forth in claim 1, the chrome having wide and narrow regions, wherein each of the narrow regions has a length not greater than 900 nm.

7. The process as set forth in claim 6, further comprising:
dry etching the alternating phase shift mask with a single or multiple Fluorine containing gas in a mixture with Oxygen.

8. The process as set forth in claim 7, wherein the dry etching provided approximately 37 nm or less nominal lateral undercut depth.

9. A phase shift structure comprising:
a quartz under-layer, comprising trenches to phase shift electromagnetic radiation;
an over-layer adjacent to the quartz under-layer, comprising opaque material patterned to allow transmission of electromagnetic radiation through the trenches of the quartz under-layer, the opaque material having wide and narrow regions with widths not less than a minimum value at which the opaque material is vulnerable to damage, wherein the quarter under-layer includes a lateral undercut depth not greater than 37 nm.

10. The phase shift structure as set forth in claim 9, wherein the opaque material comprises chrome.

11. The phase shift structure as set forth in claim 9, wherein the minimum value of the width of the opaque material is greater than 100 nm.

12. The phase shift structure as set forth in claim 9, wherein the narrow regions have lengths not greater than a maximum value at which the opaque material is vulnerable to damage.

13. The phase shift structure as set forth in claim 12, wherein the maximum value of the length of the narrow region is less than 900 nm.

14. The phase shift structure as set forth in claim 13, wherein the minimum value of the width of the narrow region is greater than 100 nm.
